(19) United States
(12) Patent Application Publication
(10) Pub. No.: US 2024/0272097 A1
(43) Pub. Date: Aug. 15, 2024

(54) TEM Orientation Mapping via Dark-Field Vector Images

(71) Applicant: Virginia Commonwealth University, Richmond, VA (US)

(72) Inventor: Carl R. Mayer, Richmond, VA (US)

(21) Appl. No.: 18/435,411

(22) Filed: Feb. 7, 2024

Related U.S. Application Data
(60) Provisional application No. 63/445,923, filed on Feb. 15, 2023.

(51) Int. Cl. G01N 23/20058; G01N 23/2251; H01J 37/28

(52) U.S. Cl. CPC G01N 23/20058; G01N 23/2251; H01J 37/28; G01N 2223/418; H01J 2237/1506; H01J 2237/2802

(57) ABSTRACT

Disclosed are various approaches for calculating crystal orientation via dark-field images from an electron microscope. In some examples, a system includes an electron microscope, at least one computing device comprising a processor and a memory, and machine-readable instructions stored in the memory. The instructions can cause the computing device to at least capture a plurality of dark-field images via the electron microscope. The computing device can calculate a crystal orientation based at least in part on data obtained from the dark-field images. The computing device can further generate an orientation map based at least in part on the crystal orientation.

### CROSS-REFERENCE TO RELATED APPLICATIONS

This application claims priority to, and the benefit of, U.S. provisional application entitled “TEM Orientation Mapping via Dark-Field Vector Images” having Ser. No. 63/445,923, filed Feb. 15, 2023, which is hereby incorporated by reference in its entirety.

### BACKGROUND

Crystallographic orientation (also known as crystallographic texture) is important to many areas of material science because nearly all material properties (e.g., strength, stiffness, resistivity, thermal conductivity, magnetization, etc.) are dependent upon the crystal orientation at the micro or nano scale. Non-random distribution of the crystallographic orientations at the micro or nano scale can lead to bulk scale effects. Changes to orientation distribution of a crystal can be induced by a variety of processes such as metallurgical deformation processes like rolling and drawing, crystallization and precipitation in solids, thin film deposition and sputtering, heat treatment, and many other processes. Often, crystal orientation is determined from 4D datasets acquired with expensive, specialized equipment such as highspeed detectors and robust image analysis algorithms.

### BRIEF DESCRIPTION OF DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 is a drawing of a network environment according to various embodiments of the present disclosure.

FIG. 2 is a drawing illustrating one example of the operation of the electron microscope in the network environment of FIG. 1 according to various embodiments of the present disclosure. FIG. 2A is an example of the operation of the electron microscope in capturing a dark-field image according to various embodiments of the present disclosure. FIG. 2B is an example of resultant dark-field images according to various embodiments of the present disclosure.

FIG. 3 is a sequence diagram illustrating one example of the interactions between the components of the network environment of FIG. 1 according to various embodiments of the present disclosure.

FIG. 4 is a flowchart illustrating one example of functionality implemented as portions of an application executed in network environment of FIG. 1 according to various embodiments of the present disclosure.

FIG. 5 is a flowchart illustrating one example of functionality implemented as portions of an application executed in network environment of FIG. 1 according to various embodiments of the present disclosure.

FIG. 6 is a flowchart illustrating one example of functionality implemented as portions of an application executed in network environment of FIG. 1 according to various embodiments of the present disclosure.

### DETAILED DESCRIPTION

Disclosed are various approaches for calculating crystal orientation via dark-field images from an electron microscope. Crystallographic orientation is important to many areas of material science because nearly all material properties are dependent upon the crystal orientation at the micro or nano scale. Often, crystal orientation is determined from four-dimensional (4D) datasets acquired with expensive, specialized equipment such as highspeed detectors and robust image analysis algorithms. Crystal orientation can also be determined using dark-field images in electron microscopy.

In optical microscopy, dark-field images can be used to enhance contrast in unstained samples and detect features on the surface of a sample that may not appear in bright-field images. Dark-field imaging in electron microscopy consists of illuminating a sample with a tilted beam of accelerated electrons, passing a diffracted beam through an aperture, and excluding the unscattered beam from the image. This produces an image with the appearance of a dark or black background with bright objects representing the structure of the sample. In most electron microscopes, the images produced have a single brightness value per pixel, resulting in a greyscale image. In order for a particular crystal to be illuminated in a dark-field image, it must satisfy two conditions: (1) the crystal planes must have a spacing which satisfies the Bragg diffraction conditions for a chosen angle of the electron beam; and (2) the crystal must be oriented such that the crystal plane normal is coplanar with the optical axis and the diffracted beam. Taking advantage of condition (2), crystallographic orientation can be mapped by tracking the illumination of different sample areas as a function of the precession angle.

Various embodiments of the present disclosure are directed to systems and methods of using vectors in dark-field electron microscopy images to map crystal orientation. To do this, a system can be arranged to capture and interpret dark-field electron microscopy images. The system can capture dark-field images using an electron microscope, produce a vector field from the images, calculate crystal orientation based at least in part on the vector field, and generate an orientation map for a particular crystallographic plane based at least in part on the calculation.

In the following discussion, a general description of the system and its components is provided, followed by a discussion of the operation of the same. Although the following discussion provides illustrative examples of the operation of various components of the present disclosure, the use of the following illustrative examples does not exclude other implementations that are consistent with the principles disclosed by the following illustrative examples.

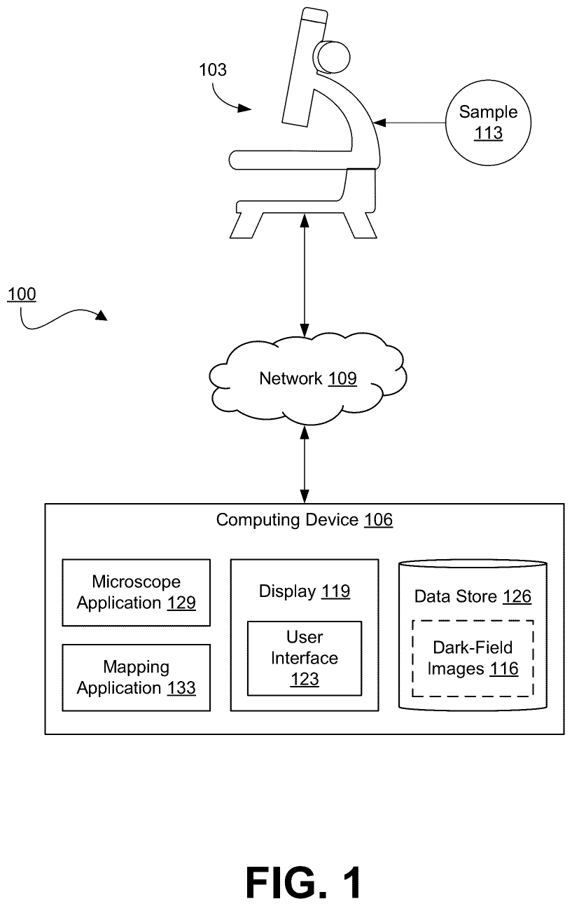

With reference to FIG. 1, shown is a network environment 100 according to various embodiments. The network environment 100 can include an electron microscope 103 and one or more computing devices 106 which can be in data communication with each other via a network 109.

The electron microscope 103 can be an instrument designed to use a beam of accelerated electrons as a source of illumination. The electron microscope 103 can be configured to receive a sample 113 of a substance having a crystalline structure and direct the electron beam at the sample 113. The electron microscope 103 can be configured to tilt and rotate the electron beam and capture images. The images obtained from the electron microscope 103 can be dark-field images 116. In some embodiments, the electron microscope 103 can send the dark-field images 116 through the network 109 to the computing device 106. In some embodiments, the electron microscope 103 can be a “smart” electron microscope, having an on-board processor-based system, such as a computer system. In at least one embodiment, the electron microscope 103 can be a specialized computing device capable of data storage, data analysis, and display capabilities. In some embodiments, the electron microscope 103 can be a transmission electron microscope. In some embodiments, the electron microscope 103 can be a serial-section electron microscope. In some embodiments, the electron microscope 103 can be a scanning transmission electron microscope.

The computing device 106 can include a processor, a memory, and/or a network interface. In some embodiments, the computing device 106 can be coupled to the network 109. The computing device 106 can be embodied in the form of a personal computer (e.g., a desktop computer, a laptop computer, or similar device), a mobile computing device (e.g., personal digital assistants, cellular telephones, smartphones, web pads, tablet computer systems, music players, portable game consoles, electronic book readers, and similar devices), media playback devices (e.g., media streaming devices, BluRay® players, digital video disc (DVD) players, set-top boxes, and similar devices), a videogame console, or other devices with like capability. The computing device 106 can include one or more displays 119, such as liquid crystal displays (LCDs), gas plasma-based flat panel displays, organic light emitting diode (OLED) displays, electrophoretic ink (“E-ink”) displays, projectors, or other types of display devices. In some instances, the display 119 can be a component of the computing device 106 or can be connected to the computing device 106 through a wired or wireless connection. In some embodiments, the display 119 can include a user interface 123. The user interface 123 can include a tilt setting configured to set a tilt angle for the electron beam, a tilt sensitivity setting configured to set a tilt sensitivity, and/or a step setting configured to set a number of steps corresponding to the desired number of dark-field images 116.

In many embodiments, the computing device 106 can have a data store 126. The data store 126 can be representative of a plurality of data stores 126, which can include relational databases or non-relational databases such as object-oriented databases, hierarchical databases, hash tables or similar key-value data stores, as well as other data storage applications or data structures. Moreover, combinations of these databases, data storage applications, and/or data structures may be used together to provide a single, logical, data store. Various data can be stored in the data store 126 that is accessible to the computing device 106. The data stored in the data store 126 is associated with the operation of the various applications or functional entities described below. This data can include dark-field images 116 from the electron microscope 103 and potentially other data.

Dark-field images 116 can include images with a dark or black background and bright objects representing the structure of the sample 113. In some embodiments, the dark-field images 116 have a single brightness value per pixel, resulting in a greyscale image.

The computing device 106 can be configured to collect, obtain, and/or receive data through the network 109, and store the data in the data store 126. The computing device 106 can be configured to render a user interface 123 on the display 119. The computing device 106 can be configured to execute various applications such as a microscope application 129, a mapping application 133, or other applications. The computing device 106 can be configured to execute applications beyond the microscope application 129 and the mapping application 133, such as email applications, social networking applications, word processors, spreadsheets, or other applications.

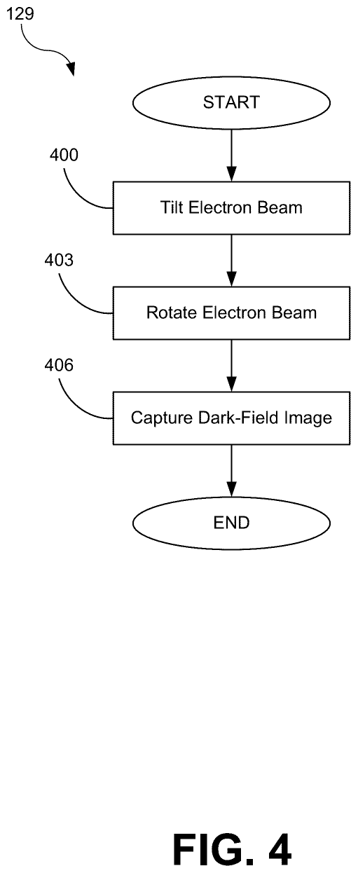

The microscope application 129 can be configured to control the electron microscope 103 by setting and adjusting the tilt of the electron beam and rotating the electron beam about the optical axis to a set precession angle. The microscope application 129 can be configured to cause the electron microscope 103 to capture dark-field images 116. The microscope application is further explained in the discussion of FIG. 4.

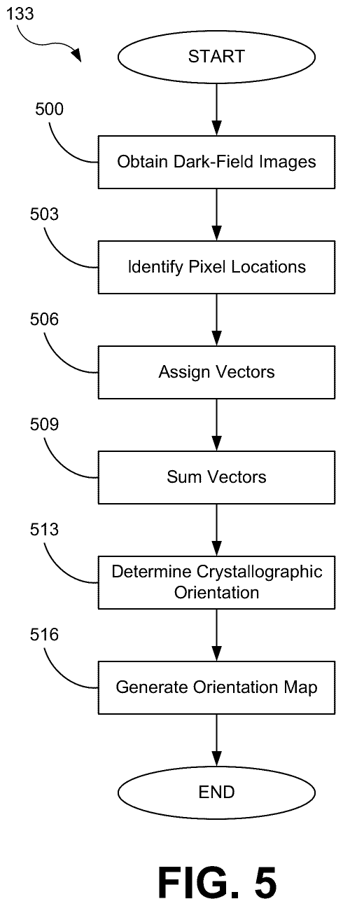

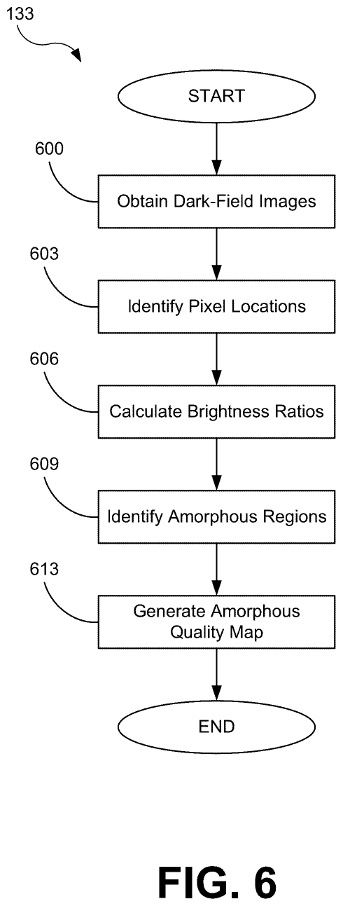

The mapping application 133 can be executed to collect, obtain, and/or receive data corresponding to dark-field images 116 generated from samples 113. The mapping application 133 can identify a pixel location, assign a vector to that pixel location, sum all vectors corresponding to the pixel location across all dark-field images 116, and determine the crystallographic orientation of the sample at the pixel location based at least in part on the vector resulting from the summation. In some embodiments, the mapping application 133 can be configured to generate an orientation map based at least in part on the crystallographic orientation. In some embodiments, the mapping application 133 can calculate a brightness ratio for each pixel location. In some embodiments, the mapping application 133 can be configured to generate an amorphous quality map based at least in part on the brightness ratios obtained from the dark-field images 116. The mapping application 133 is further explained in the discussion of FIGS. 5 and 6.

The network 109 can include wide area networks (WANs), local area networks (LANs), personal area networks (PANs), or a combination thereof. These networks can include wired or wireless components or a combination thereof. Wired networks can include Ethernet networks, cable networks, fiber-optic networks, and telephone networks such as dial-up, digital subscriber line (DSL), and integrated services digital network (ISDN) networks. Wireless networks can include cellular networks, satellite networks, Institute of Electrical and Electronic Engineers (IEEE) 802.11 wireless networks (e.g., WI-FI®), BLUETOOTH® networks, microwave transmission networks, as well as other networks relying on radio broadcasts. The network 109 can also include a combination of two or more networks 109. Examples of networks 109 can include the Internet, intranets, extranets, virtual private networks (VPNs), and similar networks.

Next, a general description of the operation of the various components of the network environment 100 is provided. Although this general description illustrates the interactions between the components of the network environment 100, other interactions or sequences of interactions are possible in various embodiments of the present disclosure. To begin, a crystal sample 113 could be inserted into an electron microscope 103. A microscope application 129 could be executed to capture dark-field images 116 of the sample 113 via the electron microscope 103. The microscope application 129 is further explained in the discussion of FIG. 4. The dark-field images 116 can be stored in a data store 126 of a computing device 106. A mapping application 133 can be used to analyze the dark-field images 116 and produce an orientation map of the crystal sample 113. In some embodiments, the mapping application 133 can send the orientation map to a user interface 123. The mapping application 133 is further explained in the discussion of FIG. 5.

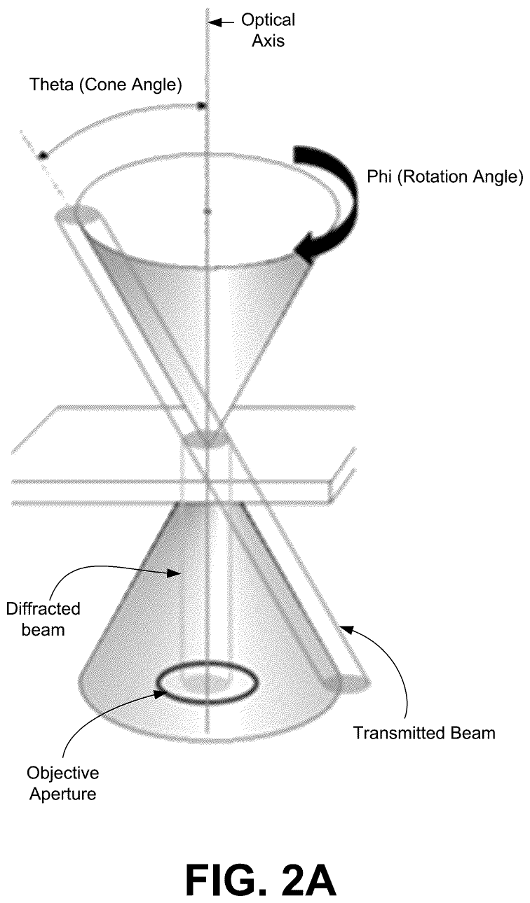

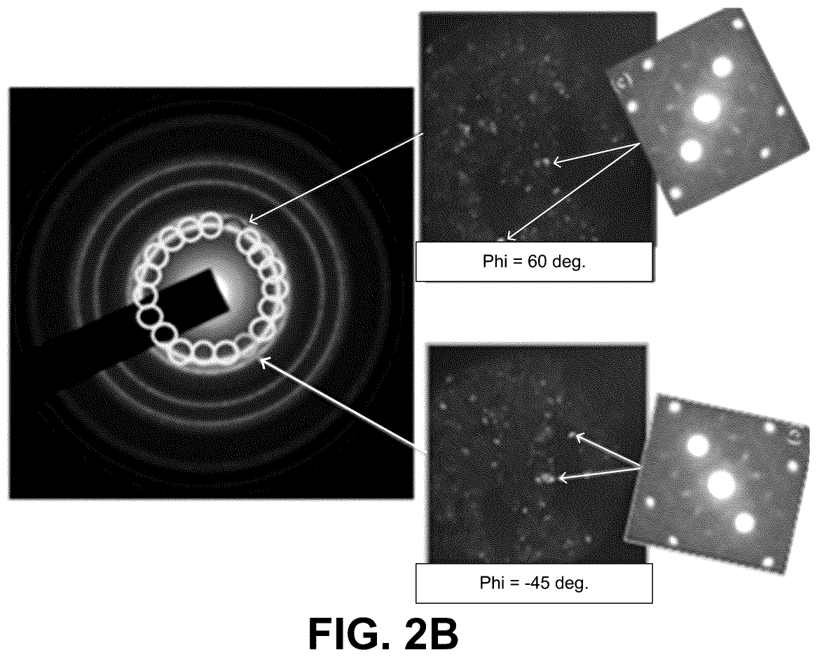

Referring next to FIG. 2, shown is an example of the operation of the electron microscope in the network environment of FIG. 1 according to various embodiments. In FIG. 2A, an example of an electron beam is shown passing through the sample at a tilt angle (cone angle Theta). An aperture can isolate the diffracted beam to produce a dark-field image 116. For each dark-field image 116 captured, the electron beam rotates about the optical axis to a precession angle (rotation angle Phi). In some embodiments, a user can define a number of incremental steps in which the electron beam must rotate about the optical axis. The number of incremental steps corresponds to the number of dark-field images 116. For each incremental step, the electron beam can rotate a number of degrees around the optical axis equal to 360° divided by the number of incremental steps.

In FIG. 2B, an example of dark-field images 116 is shown according to various embodiments. The dark-field images 116 can be combined into a single image as shown in FIG. 2B. Because the electron beam rotates around the optical axis in a full circle, the resultant dark-field combination image 116a shows the same crystal features appearing as individual bright spots in the shape of a ring. Each of the yellow rings shown in FIG. 2B corresponds to the same crystal feature captured at a different precession angle (Phi).

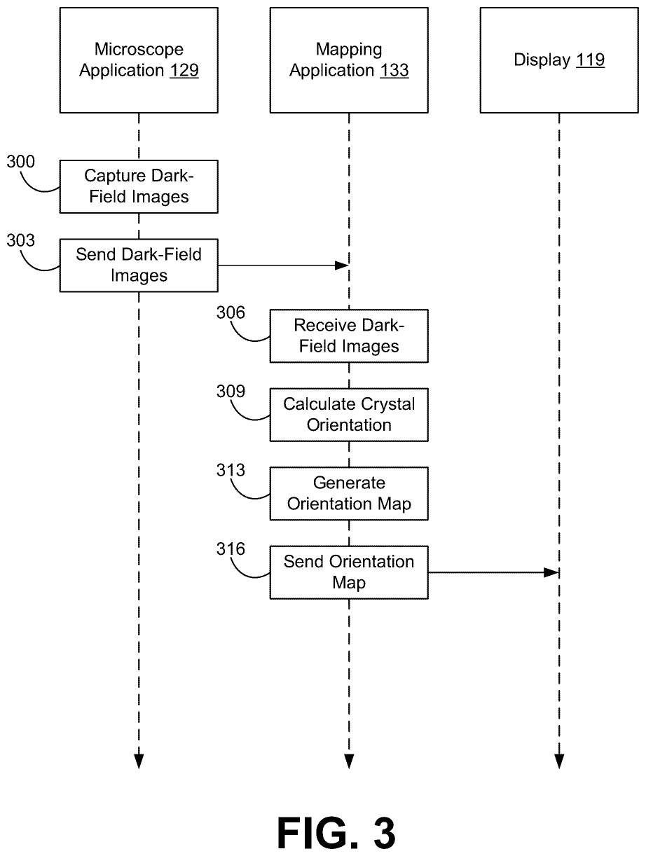

Moving next to FIG. 3, shown is a sequence diagram that provides one example of interactions between the microscope application 129, the mapping application 133, and the display 119. It is understood that the sequence diagram of FIG. 3 provides merely an example of the many different types of functional arrangements that may be employed. As an alternative, the sequence diagram of FIG. 3 may be viewed as depicting an example of elements of a method implemented with the network environment 100 of FIG. 1 according to one or more embodiments.

At block 300, the microscope application 129 can capture a plurality of dark-field images 116. To do this, a user can insert one or more crystal samples 113 into an electron microscope 103 and execute the microscope application 129 to obtain the dark-field images 116 of the sample 113. In some embodiments, the user can enter a tilt angle, tilt sensitivity, and/or a number of steps corresponding to the number of dark-field images 116 desired.

At block 303, the microscope application 129 can send the dark-field images 116 to the mapping application 133 on a computing device 106. In some embodiments, the microscope application 129 can send the dark-field images 116 to a data store 126 on the computing device 106.

At block 306, the mapping application 133 can receive the dark-field images 116 from the microscope application 129. In some embodiments, the mapping application 133 can receive the dark-field images from a data store 126 on the computing device 106.

At block 309, the mapping application 133 can calculate the orientation of the crystal. To do this, a user can execute the mapping application 133 to analyze the dark-field images 116 and calculate the orientation of the crystal at each pixel location. In some embodiments, the calculation of the crystal orientation can include analyzing the dark-field images 116 to identify the brightness of a pixel location for each dark-field image 116, and assigning a vector to the pixel location for each dark-field image 116, where the angle and magnitude of the vectors are defined by the precession angle (Phi rotation angle) of the dark-field image 116 and the pixel brightness, respectively. Since electrons are scattered symmetrically from both the front and back of crystal planes, the pixel brightness of dark-field images 116 which are captured at precession angles 180 degrees apart are summed together. Summing the vectors for all dark-field images 116 corresponding to the pixel location, the resultant vector is used to describe the orientation of the crystal at the pixel location. This process can be repeated for each pixel location of interest.

At block 313, the mapping application 133 can generate an orientation map. In some embodiments, the generation of the orientation map can include assigning a color to each pixel location based at least in part on the crystal orientation at each pixel location. The orientation map can include a color-coded visual representation of the crystallographic orientation of a sample 113.

At block 316, the mapping application 133 can send the orientation map generated at block 313 to a display 119. In some embodiments, the mapping application 133 sends the orientation map to the display 119 on the computing device 106 and causes the orientation map to be included on the user interface 123. After the orientation map is displayed, the sequence diagram of FIG. 3 ends.

Referring next to FIG. 4, shown is a flowchart that provides one example of the operation of the microscope application 129 according to various embodiments. The flowchart of FIG. 4 provides merely an example of the many different types of functional arrangements that can be employed to implement the operation of the depicted portion of the microscope application 129. Alternatively, the flowchart of FIG. 4 could be viewed as depicting a method implemented by the computing device 106.

At block 400, the microscope application 129 can tilt the electron beam of the electron microscope 103. In some embodiments, a user can set a specified angle (Theta in FIG. 2A) to which the microscope application 129 can tilt the electron beam. In some embodiments, the tilt angle is preset.

At block 403, the microscope application 129 can cause the electron beam to rotate about an optical axis. The microscope application 129 can cause the electron beam to rotate about an optical axis to a specified precession angle (Phi in FIG. 2A). In some embodiments, a user can set an incremental precession angle and the microscope application 129 can cause the electron beam to rotate about the optical axis in increments equal to the incremental precession angle.

At block 406, the microscope application 129 can cause the electron microscope 103 to capture a dark-field image 116 of the sample 113. In some embodiments, the microscope application 129 can cause the electron microscope 103 to capture a dark-field image 116 at each incremental precession angle from block 403. In some embodiments, blocks 400-406 can be repeated by the microscope application 129 for each incremental precession angle until the electron beam has made a complete rotation around the optical axis. In some embodiments, the microscope application 129 can cause the captured dark-field images 116 to be sent to a data store 126 on a computing device 106. In some embodiments, the microscope application 129 can cause the captured dark-field images 116 to be sent to a mapping application 133. After block 406, the flowchart of FIG. 4 ends.

Moving on to FIG. 5, shown is a flowchart that provides one example of the operation of the mapping application 133 according to various embodiments. The flowchart of FIG. 5 provides merely an example of the many different types of functional arrangements that can be employed to implement the operation of the depicted portion of the mapping application 133. Alternatively, the flowchart of FIG. 5 could be viewed as depicting a method implemented by the computing device 106.

At block 500, the mapping application 133 can obtain dark-field images 116. In some embodiments, the mapping application 133 can obtain dark-field images 116 from a data store 126 on a computing device 106. In some embodiments, the dark-field images 116 can be obtained from the electron microscope 103. In some embodiments, the mapping application 133 can receive the dark-field images 116 from the microscope application 129.

At block 503, the mapping application 133 can identify one or more pixel locations. In some embodiments, the mapping application 133 can identify pixel locations by identifying all pixels with a brightness value exceeding a brightness value threshold. The pixel location corresponds to a feature of the crystal sample 113. In some embodiments, one pixel location corresponds to the same crystal feature in multiple dark-field images 116. In some embodiments, one pixel location corresponds to one pixel per dark-field image 116 for multiple dark-field images 116.

At block 506, the mapping application 133 can assign a vector to a pixel in a dark-field image 116, where the pixel corresponds to a pixel location identified at block 503. The mapping application 133 can assign the vector based at least in part on the brightness value of the pixel at the pixel location and the precession angle of the dark-field image 116 corresponding to the pixel. The mapping application 133 can assign the magnitude of the vector based at least in part on the brightness value of the pixel and the direction of the vector based at least in part on the precession angle of the dark-field image 116. In some embodiments, the mapping application 133 can assign vectors for all pixels corresponding to a pixel location. In some embodiments, the mapping application 133 can assign vectors for all pixel locations.

At block 509, the mapping application 133 can sum all vectors corresponding to a pixel location. To do this, the vector assigned to the pixel location in each dark-field image 116 can be summed together with all other vectors corresponding to the pixel location across all dark-field images 116. The mapping application 133 can sum all vectors for a pixel location to yield a resultant vector corresponding to the pixel location. In some embodiments, the mapping application 133 can sum all vectors for one pixel location at a time. In some embodiments, the mapping application 133 can sum all vectors for all pixel locations at the same time, yielding a resultant vector for each pixel location.

At block 513, the mapping application 133 can determine the crystallographic orientation of the sample 113 based at least in part on the resultant vectors from block 509. The mapping application 133 can use the direction of the resultant vector at each pixel location to determine the crystal orientation at the pixel location.

At block 516, the mapping application 133 can generate an orientation map. The orientation map can be generated based at least in part on the orientation of the crystal at each pixel location as determined at block 513. In some embodiments, the mapping application 133 can assign a color to an orientation value resulting in all pixel locations with that orientation value having the same color. In some embodiments, the mapping application 133 can assign different colors to different pixel locations based at least in part on the orientation at the pixel location. In some embodiments, the mapping application 133 can send the orientation map to a display 119. After block 516, the flowchart of FIG. 5 ends.

Moving on to FIG. 6, shown is a flowchart that provides one example of the operation of the mapping application 133 according to various embodiments. The flowchart of FIG. 6 provides merely an example of the many different types of functional arrangements that can be employed to implement the operation of the depicted portion of the mapping application 133. Alternatively, the flowchart of FIG. 6 could be viewed as depicting a method implemented by the computing device 106.

At block 600, the mapping application 133 can obtain dark-field images 116. In some embodiments, the mapping application 133 can obtain dark-field images 116 from a data store 126 on a computing device 106. In some embodiments, the dark-field images 116 can be obtained from the electron microscope 103. In some embodiments, the mapping application 133 can receive the dark-field images 116 from the microscope application 129.

At block 603, the mapping application 133 can identify one or more pixel locations. In some embodiments, the mapping application 133 can identify pixel locations by identifying all pixels with a brightness value exceeding a brightness value threshold. The pixel location corresponds to a feature of the crystal sample 113. In some embodiments, one pixel location corresponds to the same crystal feature in multiple dark-field images 116. In some embodiments, one pixel location corresponds to one pixel per dark-field image 116 for multiple dark-field images 116.

At block 606, the mapping application 133 can calculate a brightness ratio corresponding to a pixel location. To do this, the mapping application 133 can calculate the ratio of the minimum brightness value to the maximum brightness value for each pixel location. In some embodiments, the mapping application 133 can use the smallest vector magnitude and the largest vector magnitude assigned to the pixel location to calculate the brightness ratio corresponding to the pixel location across all dark-field images 116. In some embodiments, the mapping application 133 can calculate the brightness ratios for one pixel location at a time. In some embodiments, the mapping application 133 can calculate the brightness ratios for all pixel locations at the same time, yielding a brightness ratio for each pixel location.

At block 609, the mapping application 133 can identify amorphous regions of the sample 113 based at least in part on the brightness ratios from block 606. The mapping application 133 can use the brightness ratio at each pixel location to indicate the existence of an amorphous region at the pixel location.

At block 613, the mapping application 133 can generate an amorphous quality map. The amorphous quality map can be generated based at least in part on the existence of amorphous regions in the crystal at each pixel location as determined at block 609. In some embodiments, the mapping application 133 can assign a color as a function of brightness ratios resulting in amorphous regions having a different color than crystalline regions. In some embodiments, the mapping application 133 can assign different colors to different pixel locations based at least in part on the existence of an amorphous region at the pixel location. In some embodiments, the mapping application 133 can send the amorphous quality map to a display 119. After block 616, the flowchart of FIG. 6 ends.

A number of software components previously discussed are stored in the memory of the respective computing devices and are executable by the processor of the respective computing devices. In this respect, the term “executable” means a program file that is in a form that can ultimately be run by the processor. Examples of executable programs can be a compiled program that can be translated into machine code in a format that can be loaded into a random access portion of the memory and run by the processor, source code that can be expressed in a proper format such as object code that is capable of being loaded into a random access portion of the memory and executed by the processor, or source code that can be interpreted by another executable program to generate instructions in a random access portion of the memory to be executed by the processor. An executable program can be stored in any portion or component of the memory, including random access memory (RAM), read-only memory (ROM), hard drive, solid-state drive, Universal Serial Bus (USB) flash drive, memory card, optical disc such as compact disc (CD) or digital versatile disc (DVD), floppy disk, magnetic tape, or other memory components.

The memory includes both volatile and nonvolatile memory and data storage components. Volatile components are those that do not retain data values upon loss of power. Nonvolatile components are those that retain data upon a loss of power. Thus, the memory can include random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, or other memory components, or a combination of any two or more of these memory components. In addition, the RAM can include static random access memory (SRAM), dynamic random access memory (DRAM), or magnetic random access memory (MRAM) and other such devices. The ROM can include a programmable read-only memory (PROM), an erasable programmable read-only memory (EPROM), an electrically erasable programmable read-only memory (EEPROM), or other like memory device.

Although the applications and systems described herein can be embodied in software or code executed by general purpose hardware as discussed above, as an alternative the same can also be embodied in dedicated hardware or a combination of software/general purpose hardware and dedicated hardware. If embodied in dedicated hardware, each can be implemented as a circuit or state machine that employs any one of or a combination of a number of technologies. These technologies can include, but are not limited to, discrete logic circuits having logic gates for implementing various logic functions upon an application of one or more data signals, application specific integrated circuits (ASICs) having appropriate logic gates, field-programmable gate arrays (FPGAs), or other components, etc. Such technologies are generally well known by those skilled in the art and, consequently, are not described in detail herein.

The flowcharts show the functionality and operation of an implementation of portions of the various embodiments of the present disclosure. If embodied in software, each block can represent a module, segment, or portion of code that includes program instructions to implement the specified logical function(s). The program instructions can be embodied in the form of source code that includes human-readable statements written in a programming language or machine code that includes numerical instructions recognizable by a suitable execution system such as a processor in a computer system. The machine code can be converted from the source code through various processes. For example, the machine code can be generated from the source code with a compiler prior to execution of the corresponding application. As another example, the machine code can be generated from the source code concurrently with execution with an interpreter. Other approaches can also be used. If embodied in hardware, each block can represent a circuit or a number of interconnected circuits to implement the specified logical function or functions.

Although the flowcharts show a specific order of execution, it is understood that the order of execution can differ from that which is depicted. For example, the order of execution of two or more blocks can be scrambled relative to the order shown. Also, two or more blocks shown in succession can be executed concurrently or with partial concurrence. Further, in some embodiments, one or more of the blocks shown in the flowcharts can be skipped or omitted. In addition, any number of counters, state variables, warning semaphores, or messages might be added to the logical flow described herein, for purposes of enhanced utility, accounting, performance measurement, or providing troubleshooting aids, etc. It is understood that all such variations are within the scope of the present disclosure.

Also, any logic or application described herein that includes software or code can be embodied in any non-transitory computer-readable medium for use by or in connection with an instruction execution system such as a processor in a computer system or other system. In this sense, the logic can include statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system. Moreover, a collection of distributed computer-readable media located across a plurality of computing devices (e.g., storage area networks or distributed or clustered filesystems or databases) may also be collectively considered as a single non-transitory computer-readable medium.

The computer-readable medium can include any one of many physical media such as magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium can be a random access memory (RAM) including static random access memory (SRAM) and dynamic random access memory (DRAM), or magnetic random access memory (MRAM). In addition, the computer-readable medium can be a read-only memory (ROM), a programmable read-only memory (PROM), an erasable programmable read-only memory (EPROM), an electrically erasable programmable read-only memory (EEPROM), or other type of memory device.

Further, any logic or application described herein can be implemented and structured in a variety of ways. For example, one or more applications described can be implemented as modules or components of a single application. Further, one or more applications described herein can be executed in shared or separate computing devices or a combination thereof. For example, a plurality of the applications described herein can execute in the same computing device, or in multiple computing devices in the same network environment 100.

In addition to the forgoing, the various embodiments of the present disclosure include, but are not limited to, the embodiments set forth in the following clauses.

Clause 1—A system, comprising an electron microscope; at least one computing device comprising a processor and a memory; and machine-readable instructions stored in the memory that, when executed by the processor, cause the computing device to at least capture a plurality of dark-field images via the electron microscope; calculate a crystal orientation based at least in part on data obtained from the dark-field images; and generate an orientation map based at least in part on the crystal orientation.

Clause 2—The system of clause 1, wherein the electron microscope is a transmission electron microscope.

Clause 3—The system of clause 1 or 2, wherein the electron microscope is a scanning electron microscope.

Clause 4—The system of any of clauses 1-3, wherein the instructions that cause the computing device to capture a plurality of dark-field images via the electron microscope further cause the computing device to tilt an electron beam of the electron microscope to a specified tilt angle; rotate the electron beam about an optical axis in a plurality of incremental steps; and capture a dark-field image at individual incremental steps.

Clause 5—The system of any of clauses 1-4, wherein the instructions, when executed, further cause the computing device to generate a user interface.

Clause 6—The system of clause 5, wherein the user interface comprises at least one of a tilt setting configured to set a tilt angle for an electron beam of the electron microscope; a tilt sensitivity setting configured to set a tilt sensitivity; or a step setting configured to set a number of steps corresponding to a number of dark-field images to capture.

Clause 7—The system of any of clauses 1-6, wherein the instructions that cause the computing device to calculate a crystal orientation further cause the computing device to identify at least one pixel location in the plurality of dark-field images; assign a vector to the at least one pixel location for individual dark-field images of the plurality of dark-field images; sum the vectors corresponding to the at least one pixel location across the plurality of dark-field images to yield a resultant vector, the resultant vector having a magnitude and a direction; and determine a crystallographic orientation at the at least one pixel location based at least in part on the direction of the resultant vector.

Clause 8—The system of clause 7, wherein the instructions that cause the computing device to assign a vector to the at least one pixel location further cause the computing device to determine a magnitude of the vector based at least in part on a brightness of a pixel corresponding to the at least one pixel location; and determine a direction of the vector based at least in part on a precession angle of the respective dark-field image.

Clause 9—The system of clause 7, wherein the instructions that cause the computing device to generate an orientation map further cause the computing device to assign a color to the at least one pixel location, the color based at least in part upon the crystallographic orientation.

Clause 10—A system, comprising at least one computing device comprising a processor and a memory; and machine-readable instructions stored in the memory that, when executed by the processor, cause the computing device to at least identify a pixel location in a plurality of dark-field images; assign a vector to the pixel location for respective individual dark-field images; sum the vectors corresponding to the pixel location across the plurality of dark-field images to yield a resultant vector, the resultant vector having a magnitude and a direction; and determine a crystallographic orientation based at least in part on the direction of the resultant vector.

Clause 111—The system of clause 10, wherein the instructions that cause the computing device to assign a vector to the pixel location further cause the computing device to determine a magnitude of the vector based at least in part on a brightness of the corresponding pixel location.

Clause 12—The system of clause 10, wherein the instructions that cause the computing device to assign a vector to the pixel location further cause the computing device to determine a direction of the vector based at least in part on a precession angle of the respective dark-field image.

Clause 13—The system of any of clauses 10-12, wherein the instructions further cause the computing device to generate an orientation map based at least in part on the crystallographic orientation.

Clause 14—The system of clause 13, wherein the instructions that cause the computing device to generate an orientation map further cause the computing device to assign a color to the pixel location, the color based at least in part upon the crystallographic orientation.

Clause 15—The system of any of clauses 10-14, wherein the instructions further cause the computing device to obtain the plurality of dark-field images from an electron microscope.

Clause 16—A method, comprising identifying at least one bright spot from a dark-field image, the at least one bright spot corresponding to a crystal area; determining a vector for the at least one bright spot; summing the vectors corresponding to the at least one bright spot across a plurality of dark-field images to yield a resultant vector; and determining an orientation of the crystal area based at least in part on a direction of the resultant vector.

Clause 17—The method of clause 16, further comprising generating an orientation map based at least in part on the orientation of the crystal area.

Clause 18—The method of clause 16 or 17, wherein determining a vector for the at least one bright spot further comprises determining a magnitude of the vector based at least in part on a brightness of the bright spot; and determining a direction of the vector based at least in part on a precession angle of the dark-field image.

Clause 19—The method of any of clauses 16-18, further comprising capturing the plurality of dark-field images with an electron microscope by tilting an electron beam to a specified tilt angle; rotating the electron beam about an optical axis in a plurality of incremental steps; and capturing a dark-field image at individual incremental steps.

Clause 20—A method, comprising tilting an electron beam of an electron microscope to a specified tilt angle, the electron beam being at a first precession angle; capturing, via the electron microscope, at least a first dark-field image of a crystal sample; identifying a pixel location in the first dark-field image; assigning a vector to the pixel location; determine a magnitude of the vector based at least in part on a pixel brightness at the pixel location; and determine a direction of the vector based at least in part on the first precession angle.

Clause 21—The method of clause 20, further comprising rotating the electron beam about an optical axis of the electron microscope to a second precession angle; capturing, via the electron microscope, at least a second dark-field image of the crystal sample; and assigning at least a second vector to the pixel location, the second vector having a magnitude determined at least in part on a pixel brightness at the pixel location and having a direction determined at least in part on the second precession angle.

Clause 22—The method of clause 21, further comprising summing the vectors corresponding to the pixel location to yield a resultant vector; and determining an orientation of the crystal sample at the pixel location based at least in part on a direction of the resultant vector.

Clause 23—The method of clause 22, further comprising generating an orientation map based at least in part on the orientation of the crystal at the pixel location.

Clause 24—A non-transitory, computer-readable medium, comprising machine-readable instructions that, when executed by a processor, cause a computing device to perform the method of any of clauses 16-23.

Clause 25—A system, comprising an electron microscope; at least one computing device comprising a processor and a memory; and machine-readable instructions stored in the memory that, when executed by the processor, cause the computing device to perform the method of any of clauses 16-23.

Disjunctive language such as the phrase “at least one of X, Y, or Z,” unless specifically stated otherwise, is otherwise understood with the context as used in general to present that an item, term, etc., can be either X, Y, or Z, or any combination thereof (e.g., X; Y; Z; X or Y; X or Z; Y or Z; X, Y, or Z; etc.). Thus, such disjunctive language is not generally intended to, and should not, imply that certain embodiments require at least one of X, at least one of Y, or at least one of Z to each be present.

It should be emphasized that the above-described embodiments of the present disclosure are merely possible examples of implementations set forth for a clear understanding of the principles of the disclosure. Many variations and modifications can be made to the above-described embodiments without departing substantially from the spirit and principles of the disclosure. All such modifications and variations are intended to be included herein within the scope of this disclosure and protected by the following claims.

Therefore, the following is claimed:

1. A system, comprising:
an electron microscope;
at least one computing device comprising a processor and a memory; and
machine-readable instructions stored in the memory that, when executed by the processor, cause the computing device to at least:
capture a plurality of dark-field images via the electron microscope;
calculate a crystal orientation based at least in part on data obtained from the dark-field images; and
generate an orientation map based at least in part on the crystal orientation.

2. The system of claim 1, wherein the electron microscope is a transmission electron microscope.

3. The system of claim 1, wherein the electron microscope is a scanning electron microscope.

4. The system of claim 1, wherein the instructions that cause the computing device to capture a plurality of dark-field images via the electron microscope further cause the computing device to:
tilt an electron beam of the electron microscope to a specified tilt angle;
rotate the electron beam about an optical axis in a plurality of incremental steps; and
capture a dark-field image at individual incremental steps.

5. The system of claim 1, wherein the instructions, when executed, further cause the computing device to generate a user interface.

6. The system of claim 5, wherein the user interface comprises at least one of:
a tilt setting configured to set a tilt angle for an electron beam of the electron microscope;
a tilt sensitivity setting configured to set a tilt sensitivity; or
a step setting configured to set a number of steps corresponding to a number of dark-field images to capture.

7. The system of claim 1, wherein the instructions that cause the computing device to calculate a crystal orientation further cause the computing device to:
identify at least one pixel location in the plurality of dark-field images;
assign a vector to the at least one pixel location for individual dark-field images of the plurality of dark-field images;
sum the vectors corresponding to the at least one pixel location across the plurality of dark-field images to yield a resultant vector, the resultant vector having a magnitude and a direction; and
determine a crystallographic orientation at the at least one pixel location based at least in part on the direction of the resultant vector.

8. The system of claim 7, wherein the instructions that cause the computing device to assign a vector to the pixel location further cause the computing device to:
determine a magnitude of the vector based at least in part on a brightness of a pixel corresponding to the at least one pixel location; and
determine a direction of the vector based at least in part on a precession angle of the respective dark-field image.

9. The system of claim 7, wherein the instructions that cause the computing device to generate an orientation map further cause the computing device to assign a color to the pixel location, the color based at least in part upon the crystallographic orientation.

10. A system, comprising:
at least one computing device comprising a processor and a memory; and
machine-readable instructions stored in the memory that, when executed by the processor, cause the computing device to at least:
identify a pixel location in a plurality of dark-field images;
assign a vector to the pixel location for respective individual dark-field images;
sum the vectors corresponding to the pixel location across the plurality of dark-field images to yield a resultant vector, the resultant vector having a magnitude and a direction; and
determine a crystallographic orientation based at least in part on the direction of the resultant vector.

11. The system of claim 10, wherein the instructions that cause the computing device to assign a vector to the pixel location further cause the computing device to determine a magnitude of the vector based at least in part on a brightness of the corresponding pixel location.

12. The system of claim 10, wherein the instructions that cause the computing device to assign a vector to the pixel location further cause the computing device to determine a direction of the vector based at least in part on a precession angle of the respective dark-field image.

13. The system of claim 10, wherein the instructions further cause the computing device to generate an orientation map based at least in part on the crystallographic orientation.

14. The system of claim 13, wherein the instructions that cause the computing device to generate an orientation map further cause the computing device to assign a color to the pixel location, the color based at least in part upon the crystallographic orientation.

15. The system of claim 10, wherein the instructions further cause the computing device to obtain the plurality of dark-field images from an electron microscope.

16. A method, comprising:
identifying at least one bright spot from a dark-field image, the at least one bright spot corresponding to a crystal area;
determining a vector for the at least one bright spot;
summing the vectors corresponding to the at least one bright spot across a plurality of dark-field images to yield a resultant vector; and
determining an orientation of the crystal area based at least in part on a direction of the resultant vector.

17. The method of claim 16, further comprising generating an orientation map based at least in part on the orientation of the crystal area.

18. The method of claim 16, wherein determining a vector for the at least one bright spot further comprises:
determining a magnitude of the vector based at least in part on a brightness of the bright spot; and
determining a direction of the vector based at least in part on a precession angle of the dark-field image.

19. The method of claim 16, further comprising capturing the plurality of dark-field images with an electron microscope.

20. The method of claim 19, wherein capturing the plurality of dark-field images further comprises:
tilting an electron beam to a specified tilt angle;
rotating the electron beam about an optical axis in a plurality of incremental steps; and
capturing a dark-field image at individual incremental steps.
